(19) United States
(12) Patent Application Publication
(10) Pub. No.: US 2025/0140725 A1
(43) Pub. Date: May 1, 2025

(54) BUMP ARRANGEMENT OF INTEGRATED CIRCUITS FOR FLIP CHIP BONDING

(71) Applicant: Synaptics Incorporated, San Jose, CA (US)

(72) Inventors: Shinya Suzuki, Tokyo (JP); Naoki Hasegawa, Tokyo (JP); Yuji Oyama, Saitama (JP); Keigo Takasaki, Saitama (JP); Kenichi Kasuga, Chiba (JP); Tomohiro Fukaya, Tokyo (JP)

(21) Appl. No.: 18/498,647

(22) Filed: Oct. 31, 2023

(51) Int. Cl. H01L 23/00

(52) U.S. Cl. CPC H01L 24/14; H01L 24/16; H01L 2224/1403; H01L 2224/14131; H01L 2224/14163; H01L 2224/16225; H01L 2924/1426

(57) ABSTRACT

An integrated circuit includes a semiconductor chip, a first bump row, and a second bump row. The semiconductor chip has a first edge oriented in a first planar direction. The first bump row includes a plurality of first bumps aligned in the first planar direction along the first edge, and the second bump row includes a plurality of second bumps aligned in the first planar direction. The second bump row is located farther from the first edge of the semiconductor chip than the first bump row. A first width of the first bumps in the first planar direction is narrower than a second width of the second bumps in the first planar direction.

### TECHNICAL FIELD

This disclosure generally relates to bump arrangement of integrated circuits for flip chip bonding.

### BACKGROUND

Flip chip bonding is a widely used technology for bonding integrated circuit (IC) chips to device substrates. An IC chip adapted to flip chip bonding may include an array of bumps, and the bumps may be bonded to bond pads formed on a device substrate to provide mechanical and electrical connections between the IC chip and the device substrate. The bond pads may be coupled to circuit elements disposed on the device substrate via routing traces or interconnections. The use of flip chip bonding effectively facilitates the miniaturization of electronic devices incorporating IC chips. One example of flip chip bonding is chip-on-glass (COG) technology, in which an IC chip is flip-chip bonded to a glass substrate. The COG technology is widely used to bond display driver ICs to glass substrates of display panels.

In order to interface a large number of signals, some IC chips adapted to flip chip bonding may include a large number of bumps. For example, a display driver IC chip configured to drive a display panel (e.g., an organic light emitting diode (OLED) display panel, a micro light emitting diode (LED) display panel, and a liquid crystal display (LCD) panel) may include several hundred to several thousand bumps for outputting data signals to the display panel via the bumps. The increase in the number of bumps, which would be accompanied by an increase in the number of bond pads on the device substrate, may cause difficulties in the placement and routing of the bumps, the bond pads, and the routing traces coupled to the bond pads.

### SUMMARY

This summary is provided to introduce a selection of concepts in a simplified form that are further described below. This summary is not intended to necessarily identify key features or essential features of the present disclosure. The present disclosure may include the following various aspects and embodiments.

In an exemplary embodiment, the present disclosure provides an integrated circuit that includes a semiconductor chip, a first bump row, and a second bump row. The semiconductor chip has a first edge oriented in a first planar direction. The first bump row includes a plurality of first bumps aligned in the first planar direction along the first edge, and the second bump row includes a plurality of second bumps aligned in the first planar direction. The second bump row is located farther from the first edge of the semiconductor chip than the first bump row. A first width of the first bumps in the first planar direction is narrower than a second width of the second bumps in the first planar direction.

In another exemplary embodiment, the present disclosure provides a display device that includes a display panel and a display driver integrated circuit (IC). The display driver IC is bonded on the display panel. The display driver IC includes a semiconductor chip, a first bump row, and a second bump row. The semiconductor chip includes a first edge oriented in a first planar direction. The first bump row includes a plurality of first bumps aligned in the first planar direction along the first edge. The second bump row includes a plurality of second bumps aligned in the first planar direction. The second bump row is located farther from the first edge of the semiconductor chip than the first bump row. A first width of the first bumps in the first planar direction is narrower than a second width of the second bumps in the first planar direction.

In yet another exemplary embodiment, the present disclosure provides a method. The method includes generating data voltages by a display driver IC. The display driver IC includes a semiconductor chip, a first bump, and a second bump. The semiconductor chip has a first edge oriented in a first planar direction. The first bump row includes a plurality of first bumps aligned in the first planar direction along the first edge, and the second bump row includes a plurality of second bumps aligned in the first planar direction. The second bump row is located farther from the first edge of the semiconductor chip than the first bump row. A first width of the first bumps in the first planar direction is narrower than a second width of the second bumps in the first planar direction. The method further includes providing the data voltages to a display panel via the plurality of first bumps and the plurality of second bumps.

Further features and aspects are described in additional detail below with reference to the attached drawings.

### BRIEF DESCRIPTION OF THE DRAWINGS

FIG. 1 shows an example configuration of a display device.

FIG. 2 shows an example side view configuration of the display device shown in FIG. 1.

FIG. 3 is a partial enlarged side view of a display device showing an example bonding structure for bonding a display driver IC to a display panel.

FIG. 4 shows example arrangements of bump arrays on the main surface of a semiconductor chip.

FIG. 5A is a partial enlarged view of an example bump array.

FIG. 5B is a partial enlarged view showing an example arrangement of conductors on a substrate of a display panel.

FIG. 6A shows the positional relationship between the bumps shown in FIG. 5A and the routing traces shown in FIG. 5B.

FIG. 6B shows an example of the effect of increasing the number of bump rows.

FIG. 7 shows an example scheme for facilitating the placement of routing traces coupled to bond pads, according to one or more embodiments.

FIG. 8 shows an example configuration of a display driver IC configured to drive a display panel, according to one or more embodiments.

FIG. 9A is a partial enlarged view of the output bump array shown in FIG. 8, according to one or more embodiments.

FIG. 9B is a partial enlarged view showing an example configuration of a display panel driven by the display driver IC shown in FIG. 8, according to one or more embodiments.

To facilitate understanding, identical reference numerals have been used, where possible, to designate elements that are common to the figures. It is contemplated that elements disclosed in one embodiment may be utilized in other embodiments without specific recitation. Suffixes may be attached to reference numerals for distinguishing elements from each other. The drawings referred to herein should not be understood as being drawn to scale unless specifically noted. Also, the drawings are often simplified and details or components omitted for clarity of presentation and explanation. The drawings and discussion serve to explain principles discussed below.

### DETAILED DESCRIPTION

The following detailed description is exemplary in nature and is not intended to limit the disclosure or the application and uses of the disclosure. Furthermore, there is no intention to be bound by any expressed or implied theory presented in the preceding background, summary and brief description of the drawings, or the following detailed description.

In the following detailed description, numerous specific details are set forth in order to provide a more thorough understanding of the disclosed technology. However, it will be apparent to one of ordinary skill in the art that the disclosed technology may be practiced without these specific details. In other instances, well-known features have not been described in detail to avoid unnecessarily complicating the description.

The term “coupled” as used herein means connected directly to or connected through one or more intervening components or circuits. Further, throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

As discussed above, some IC chips adapted to flip chip bonding may include a large number of bumps to interface an increased number of signals. For example, with the recent increase in display resolution, a display driver IC configured to drive a display panel (e.g., an OLED display panel, a micro-LED display panel, and an LCD panel) may include an increased number of bumps to provide an increased number of signals (e.g., data voltages used to update pixels) to the display panel. A display driver IC chip may include several hundred to several thousand bumps to output data signals to the display panel via the bumps. As the number of bumps increases, the number of bond pads bonded to the bumps and the number of routing traces coupled to the bond pads may also increase.

To facilitate placement of the bond pads and routing traces, the bumps may be arranged in a “staggered” arrangement. In a staggered bump arrangement, the bumps may be arranged in a plurality of rows with corresponding bumps of adjacent rows offset from each other while the bond pads may be arranged at positions determined in accordance with the staggered bump arrangement. The staggered bump arrangement may allow an increasing number of routing traces to be placed in the bond pad array while reducing the area required to arrange the bumps on the IC chip.

In implementations where a large number of bumps are arranged within a limited width of the bump array, an increased number of bump rows may be arranged in the bump array. The present disclosure recognizes that an increase in the number of bump rows may cause difficulties in the placement of routing traces coupled to the bond pads bonded to the bumps, as the number of routing traces passing between adjacent bumps (or between adjacent bond pads) may also increase. The present disclosure provides implementations to facilitate the placement of routing traces coupled to bond pads in the case where an increased number of bump rows are arranged in the bump array. It should be noted that while the following primarily describes implementations based on display driver ICs, the technologies can be applied to other types of ICs.

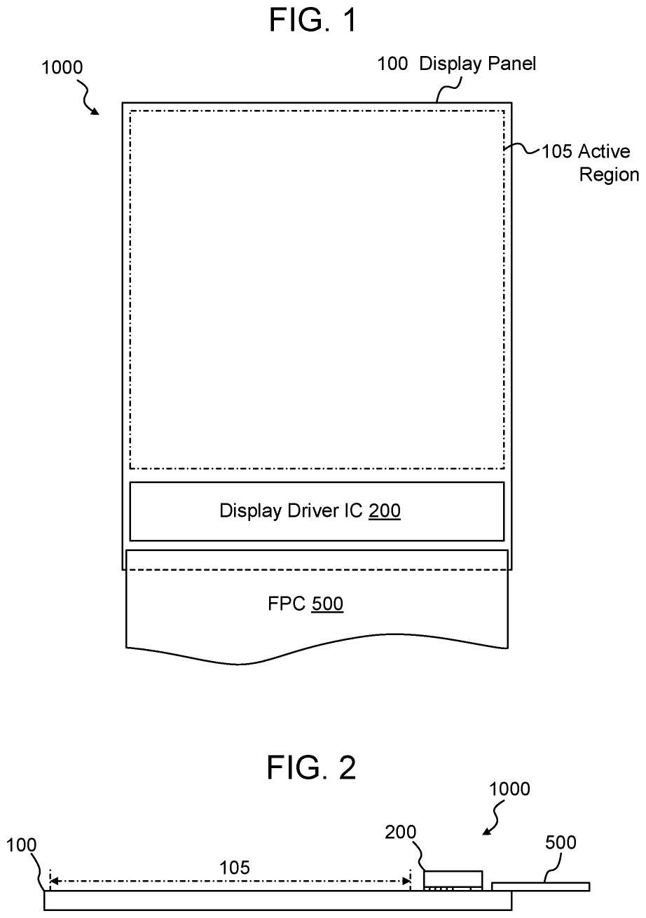

FIG. 1 shows an example configuration of a display device 1000. In the shown example, the display device 1000 includes a display panel 100, a display driver IC 200, and a flexible printed circuit board (FPC) 500. The display panel 100 includes an array of pixels arranged in an active region 105. In one implementation, the display panel 100 is an OLED display panel. In an alternative implementation, the display panel 100 may be a micro-LED display panel, an LCD panel or another type of display panel. The display driver IC 200 is configured to drive or update the pixels of the display panel 100 based on image data generated by an image source, such as an application processor (AP), a central processing unit (CPU), or other processors configured to generate the image data. The FPC 500 includes routing traces or interconnections to provide the image data and other control data and/or control signals to the display driver IC 200. The FPC 500 may further include other components (e.g., one or more ICs, capacitors and/or other passive elements) for signal processing and/or transformation.

FIG. 2 shows an example side view configuration of the display device 1000 shown in FIG. 1. In one or more embodiments, the display driver IC 200 is mounted on the display panel 100 using flip chip bonding technology. The FPC 500 is bonded to the display panel 100 to provide signals to the display driver IC 200 via conductors formed on the display panel 100.

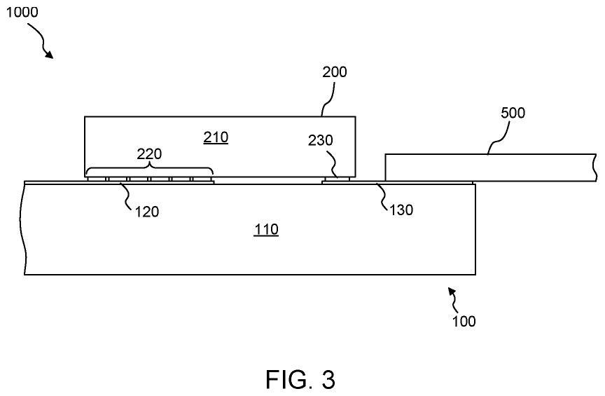

FIG. 3 is a partial enlarged side view of the display device 1000 showing an example bonding structure for bonding the display driver IC 200 to the display panel 100. In the shown example, the display driver IC 200 includes a semiconductor chip 210 having a main surface on which bump arrays 220 and 230 are formed to achieve flip chip bonding. The main surface referred to herein is the surface facing the display panel 100. The bump array 220 includes a set of bumps used by the display driver IC 200 to output signals (e.g., data voltages used to update pixels on the display panel 100) to components on the display panel 100. Accordingly, the bump array 220 may also be referred to hereinafter as the output bump array 220. The bump array 230 includes a set of bumps used to input data and/or signals (e.g., display data, control data, control signals, and other data/signals) to the display driver IC 200. Accordingly, the bump array 230 may also be referred to hereinafter as the input bump array 230. The display panel 100 includes a substrate 110 and conductors 120 and 130 formed on the substrate 110. In one implementation, the conductors 120 and 130 may be formed of indium tin oxide (ITO). The bumps of the output bump array 220 are bonded to the conductors 120, and the bumps of the input bump array 230 are bonded to the conductors 130. Anisotropic conductive film (ACF) layers may be used to bond the bump arrays 220 and 230 to the conductors 120 and 130. The conductors 120 are used to provide signals from the display driver IC 200 to relevant components of the display panel 100 (e.g., pixels), while the conductors 130 are used to provide signals and/or data (e.g., the image data, control data and/or control signals) to the display driver IC 200.

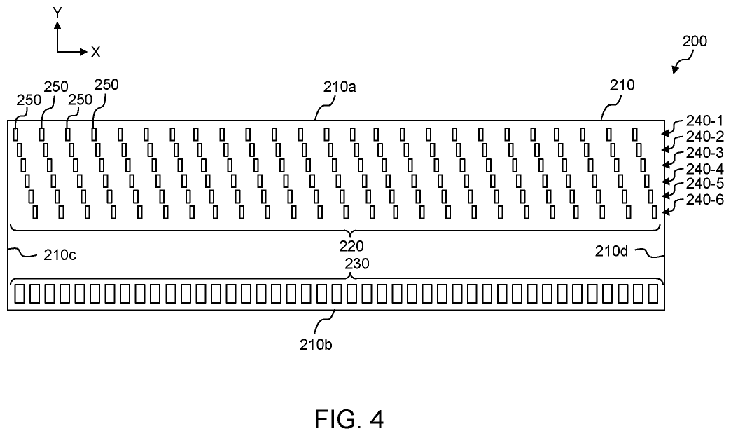

FIG. 4 shows example arrangements of the bump arrays 220 and 230 on the main surface of the semiconductor chip 210. In FIG. 4 (and subsequent figures), planar directions in the main surface of the semiconductor chip 210 may be specified with X- and Y-axes defined perpendicular to each other. In the shown embodiment, the main surface of the semiconductor chip 210 has a rectangular shape with long edges 210a, 210b and short edges 210c and 210d. The long edges 210a and 210b are oriented in a first planar direction parallel to the X-axis (which may also be referred to as the horizontal planar direction), while the short edges 210c and 210d are oriented in a second planar direction parallel to the Y-axis (which may also be referred to as the vertical planar direction). The semiconductor chip 210 is arranged such that the long edge 210a faces the active region 105 of the display panel 100.

The output bump array 220 has a “staggered” bump arrangement in which bumps are arranged in a plurality of rows with corresponding bumps of adjacent rows offset from each other. In the shown example, the output bump array 220 includes a plurality of bump rows 240 each including a plurality of bumps 250 aligned in the horizontal planar direction (i.e., the X-axis direction), wherein the corresponding bumps 250 in adjacent bump rows 240 are located offset from each other in the horizontal planar direction. In the shown example, the output bump array 220 includes six bump rows 240-1, 240-2, 240-3, 240-4, 240-5, and 240-6. The bump row 240-1 is the closest to the long edge 210a, the bump row 240-2 is the second closest to the long edge 210a, the bump row 240-3 is the third closest to the long edge 210a, and so on. The bumps 250-2 of the bump row 240-2 are located offset in the horizontal planar direction from the corresponding bumps 250-1 of the bump row 240-1, the bumps 250-3 of the bump row 240-3 are located offset in the horizontal planar direction from the corresponding bumps 250-2 of the bump row 240-2, and so on. While six bump rows 240 are shown in FIG. 4, the output bump array 220 may include fewer or more than six bump rows.

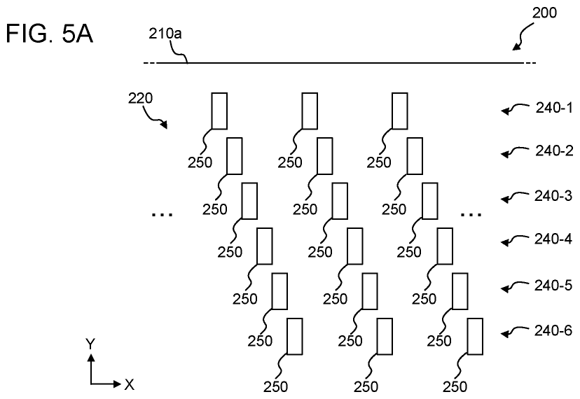

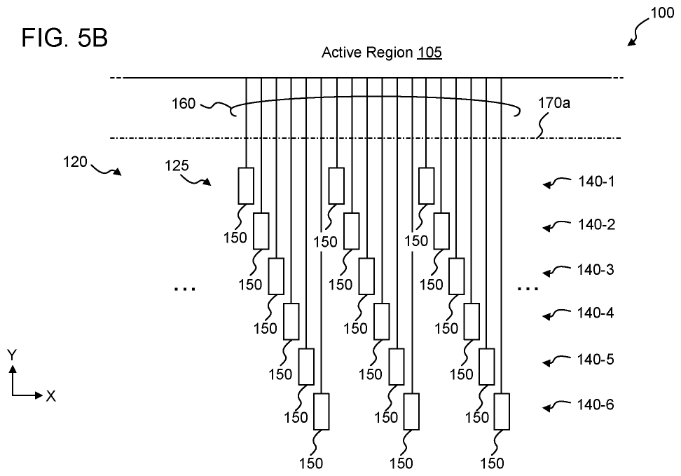

FIG. 5A is a partial enlarged view of the output bump array 220 of FIG. 4. As described above, the output bump array 220 includes six bump rows 240-1, 240-2, 240-3, 240-4, 240-5, and 240-6. The bump rows 240-1 to 240-6 may be collectively referred to as the bump rows 240 when the bump rows 240-1 to 240-6 are not distinguished from one another. Each of the bump rows 240-1, 240-2, 240-3, 240-4, 240-5, and 240-6 includes an array of bumps 250 aligned in the horizontal planar direction (or the X-axis direction).

FIG. 5B is a partial enlarged view showing an example arrangement of the conductors 120 disposed on the substrate 110 of the display panel 100. Shown in FIG. 5B is the portion of the conductors 120 coupled to the portion of the output bump array 220 shown in FIG. 5A. The conductors 120 form a bond pad array 125 that includes a plurality of bond pad rows 140-1, 140-2, 140-3, 140-4, 140-5, and 140-6. Each of the bond pad rows 140-1 to 140-6 includes an array of bond pads 150 aligned in the horizontal planar direction. The bond pad rows 140-1 to 140-6 may be collectively referred to as the bond pad rows 140 when the bond pad rows 140-1 to 140-6 are not distinguished from one another.

The bond pads 150 of each bond pad row 140 are respectively bonded to corresponding bumps 250 of the corresponding bump row 240. More specifically, the bond pads 150 of the bond pad rows 140-1 are bonded to the corresponding bumps 250 of the bump row 240-1, the bond pads 150 of the bond pad rows 140-2 are bonded to the corresponding bumps 250 of the bump row 240-2, the bond pads 150 of the bond pad rows 140-3 are bonded to the corresponding bumps 250 of the bump row 240-3, and so on. In other words, the bond pads 150 of the bond pad rows 140-i are bonded to the corresponding bumps 250 of the bump row 240-i, where i is any integer between one and six, inclusive. The planar shapes (e.g., the width in the horizontal planar (or X-axis) direction and the height in the vertical planar (or Y-axis) direction) of the bond pads 150 are substantially the same as those of the corresponding bumps 250.

The conductors 120 further include routing traces 160 coupled to the bond pads 150, respectively. The routing traces 160 provide electrical connections between the bond pads 150 and circuit elements provided in the active region 105 of the display panel 100, such as source lines, pixels, and multiplexers configured to select source lines coupled to the bond pads 150, if such multiplexers are provided in the active region 105. Signals and/or voltages output from the bumps 250 of the display driver IC 200 (e.g., data voltages used to drive the pixels of the display panel 100) are provided to the active region 105 via the corresponding bond pads 150 and routing traces 160. As shown in FIG. 5B, where the dashed-dotted line 170a indicates the projection of the long edge 210a of the display driver IC 200 onto the display panel 100, the routing traces 160 pass under the long edge 210a of the display driver IC 200. In addition, a series of five routing traces 160 respectively coupled to bond pads 150 of bond pad rows 140-2 to 140-6 pass between every two of the bond pads 150 of the bond pad rows 140-1.

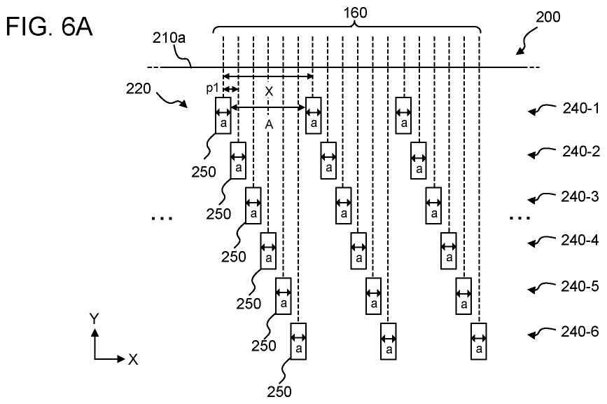

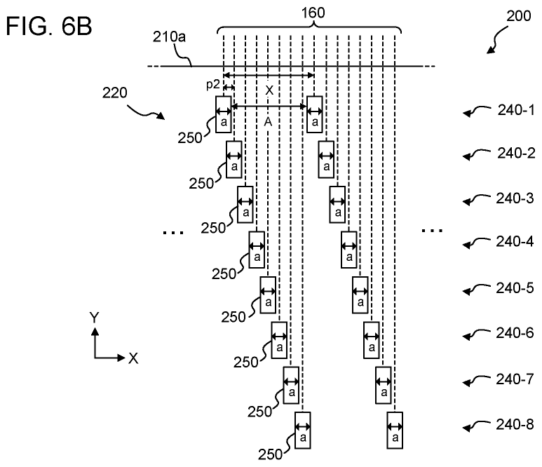

FIG. 6A shows the positional relationship between the bumps 250 of the display driver IC 200 shown in FIG. 5A and the routing traces 160 of the display panel 100 shown in FIG. 5B. It is noted that the routing traces 160 are indicated by dashed lines as the routing traces 160 are actually located under the display driver IC 200. In the example shown in FIG. 6A, all the bumps 250 have the same horizontal width of “a”. In FIG. 6A, “A” indicates the spacing between horizontally adjacent two bumps 250 in each bump row 240. Further, “X” indicates the horizontal pitch between adjacent two bumps 250 in each bump row 240. The horizontal pitch of adjacent two bumps 250, as referred to herein, is the distance in the horizontal planar direction between the vertical centerlines of the horizontally adjacent two bumps 250. In the example shown in FIG. 6A, where the number of bump rows 240 is six, the pitch “p1” between horizontally adjacent two routing traces 160 is X/6.

With the recent increase in display resolution, a display driver IC may be configured to provide an increased number of signals (e.g., data voltages used to drive or update pixels) to the display panel. The increase in the number of signals provided to the display panel may be accompanied by an increase in the number of bumps and bond pads. In such cases, an increased number of bump rows may be arranged in the bump array.

FIG. 6B shows an example effect of increasing the number of bump rows, wherein eight bump rows 240-1 to 240-8 are arranged in the bump array 220. In the example shown in FIG. 6B, the horizontal pitch “X” between adjacent two bumps 250 in each bump row 240 is unchanged from the example shown in FIG. 6A, because increasing the horizontal pitch “X” between adjacent two bumps 250 would undesirably increase the horizontal width of the bump rows 240 and thereby increase the chip size of the display driver IC 200. In the example shown in FIG. 6B, the pitch “p2” between horizontally adjacent two routing traces 160 is X/8, which is smaller than the pitch “p1” between horizontally adjacent two routing traces 160 in the example shown in FIG. 6A.

The present disclosure recognizes that increasing the number of bump rows 240 undesirably increases the number of routing traces 160 that pass between horizontally adjacent two bumps 250, thereby reducing the pitch between horizontally adjacent two routing traces 160. Because the routing trace design rules define the minimum line width of routing traces, the minimum spacing between adjacent routing traces, and other constraints on routing trace placement, reducing the pitch between horizontally adjacent two routing traces 160 may make it difficult to design the routing traces 160 within the design rules. Presented in the following are example embodiments for facilitating the placement of routing traces coupled to bond pads in the case where an increased number of bump rows are arranged in the bump array. It should be noted that while the following primarily describes embodiments based on display driver ICs, the techniques disclosed herein may be applied to other types of ICs.

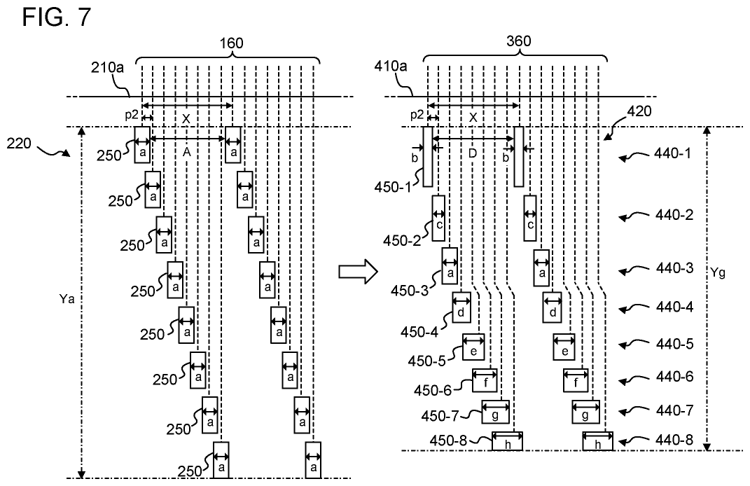

FIG. 7 shows an example arrangement for facilitating the placement of routing traces coupled to bond pads, according to one or more embodiments. The right part of FIG. 7 shows an example arrangement of a bump array 420 for facilitating routing placement according to one or more embodiments, while the left part of FIG. 7 shows the bump arrangement shown in FIG. 6B as comparative example. In the right part of FIG. 7, numeral 410a denotes the long edge of the display driver IC, which corresponds to the long edge 210a of the display driver IC 200.

As shown in the right part of FIG. 7, the bump array 420 includes eight bump rows 440-1, 440-2, 440-3, 440-4, 440-5, 440-6, 440-7, and 440-8. The bump row 440-1 is the closest from the long edge 410a, the bump row 440-2 is the second closest, the bump row 440-3 is the third closest, and so on. Each of the bump rows 440-1 to 440-8 includes bumps 450 (two shown for each bump row) aligned in the horizontal planar direction. The bumps 450 of the bump rows 440-1, 440-2, 440-3, 440-4, 440-5, 440-6, 440-7, and 440-8 may be referred to as the bumps 450-1, 450-2, 450-3, 450-4, 450-5, 450-6, 450-7, and 450-8, respectively.

In the shown embodiment, the horizontal widths of the bumps 450-1, 450-2, 450-3, 450-4, 450-5, 450-6, 450-7, and 450-8 are narrower as the respective distances from the long edge 410a of the display driver IC decrease. The “horizonal width” of a bump referred to herein is the height of the bump in the horizontal planar (or X-axis) direction. More specifically, the bumps 450-1, 450-2, 450-3, 450-4, 450-5, 450-6, 450-7, and 450-8 have horizontal widths of “b”, “c”, “a”, “d”, “e”, “f”, “g”, and “h”, respectively, where b<c<a<d<e<f<g<h. In this bump arrangement, the horizontal pitch between adjacent bumps 450 is wider as the distance from the long edge 410a decreases. Such a bump arrangement effectively facilitates the placement of an increased number of routing traces passing between two horizontally adjacent bumps 450 by relaxing the constraints on the widths and/or pitches of routing traces 360 that pass between two adjacent bumps 450.

More specifically, the bumps 450-1 of the bump row 440-1, which is the closest to the long edge 410a of the semiconductor chip 410, have the narrowest horizontal width “b”. While the largest number (seven in the shown embodiment) of routing traces 360 pass between two adjacent bumps 450-1, the use of the narrowest horizontal width “b” for the bumps 450-1 allows the spacing “D” between the two adjacent bumps 450-1 to be increased, thereby effectively relaxing the constraints on the width of the routing traces 360 and the spacing or pitch between two adjacent routing traces 360. In some embodiments, the horizontal width “b” of the bumps 450-1 of the bump row 440-1 may be the allowed minimum horizontal width of bumps defined by the design rule. Further, the bumps 450-2 of the bump row 440-2, which is the second closest to the long edge 410a of the semiconductor chip 410, have the second narrowest horizontal width “c”. While the second largest number (six in the shown embodiment) of routing traces 360 pass between two adjacent bumps 450-2, the use of the second narrowest horizontal width “c” for the bumps 450-2 allows the spacing between the two adjacent bumps 450-2 to be increased, also effectively relaxing the constraints on the width of the routing traces 360 and the spacing or pitch between two adjacent routing traces 360.

Meanwhile, the bumps 450-8 of the bump row 440-8, which is the farthest from the long edge 410a of the semiconductor chip 410, have the widest horizontal width “h”. The use of the widest horizontal width “h” for the bumps 450-8 does not however affect the routing of the routing traces 360 because none of the routing traces 360 passes between two adjacent bumps 450-8. Similarly, the use of the second widest horizontal width “g” for the bumps 450-7 of the bump row 440-7, which is the second farthest from the long edge 410a of the semiconductor chip 410, does not however affect the routing of the routing traces 360 because only one routing trace 360 passes between two adjacent bumps 450-7.

In one or more embodiments, the vertical heights (or the heights in the vertical planar direction) of the bumps 450-1, 450-2, 450-3, 450-4, 450-5, 450-6, 450-7, and 450-8 are adjusted to decrease as the distance from the long edge 410a of the semiconductor chip 410 increases. The “vertical height” of a bump referred to herein is the height of the bump in the vertical planar (or Y-axis) direction. More specifically, the bumps 450-1 of the bump row 440-1, which is the closest to the long edge 410a of the semiconductor chip 410, have the largest vertical height, the bumps 450-2 of the bump row 440-2, which is the second closest to the long edge 410a of the semiconductor chip 410, have the second largest vertical height, the bumps 450-3 of the bump row 440-3, which is the third closest to the long edge 410a of the semiconductor chip 410, have the third largest vertical height, and so on. The decreasing vertical heights of the bumps 450-1, 450-2, 450-3, 450-4, 450-5, 450-6, 450-7, and 450-8 with the distance from the long edge 410a allows the total vertical height “Yg” of the bump array 420 to be reduced. In the implementation shown in FIG. 7, the total vertical height “Yg” of the bump array 420 is less than the total vertical height “Ya” of the bump array 220, in which the vertical heights of the bumps 250 are constant.

In one or more embodiments, the horizontal planar widths and vertical planar heights of the respective bumps 450-1 to 450-8 may be adjusted such that the areas (or planar areas) of the bumps 450-1 to 450-8 are substantially the same. The term “substantially the same” as used herein may mean that the differences are within the range of manufacturing variation. The arrangement in which the areas of the bumps 450-1 to 450-8 are substantially the same allows the contact resistances between the bumps 450-1 to 450-8 and the bond pads bonded thereto to be the same, which may improve the performance of circuits electrically connected to the bumps 450-1 to 450-8. For example, in embodiments where the display driver IC is configured to provide data voltages to pixels of the display panel via the bumps 450-1 to 450-8 to drive the pixels, the bump arrangement in which the contact resistances between the bumps 450-1 to 450-8 and the bond pads bonded thereto are the same may suppress mura or brightness unevenness potentially caused by variations in the contact resistances.

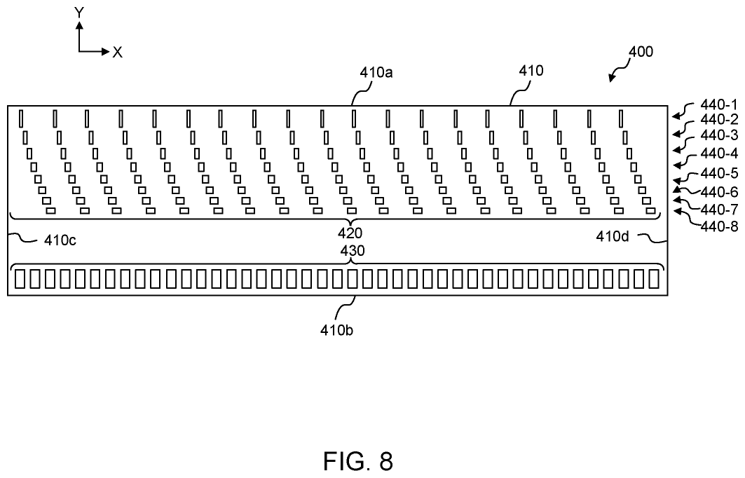

FIG. 8 shows an example configuration of a display driver IC 400 configured to drive a display panel, such as an OLED display panel, a micro-LED display panel, and an LCD panel, according to one or more embodiments. In the shown embodiment, the display driver IC 400 includes a semiconductor chip 410, an output bump array 420 and an input bump array 430. The display driver IC 400 is configured to generate data voltages and provide the data voltages to the display panel via bumps of the output bump array 420 to drive or update pixels of the display panel with the data voltages. In the shown embodiment, the main surface of the semiconductor chip 410 has a rectangular shape with long edges 410a, 410b and short edges 410c and 410d. The long edges 410a and 410b are oriented in the horizontal planar direction parallel to the X-axis while the short edges 410c and 410d are oriented in the vertical direction parallel to the Y-axis. It is noted that the X- and Y-axes are both oriented in planar directions of the main surface of the semiconductor chip 410. The output bump array 420 is located adjacent to the long edge 410a, while the input bump array 430 is located adjacent to the long edge 410b.

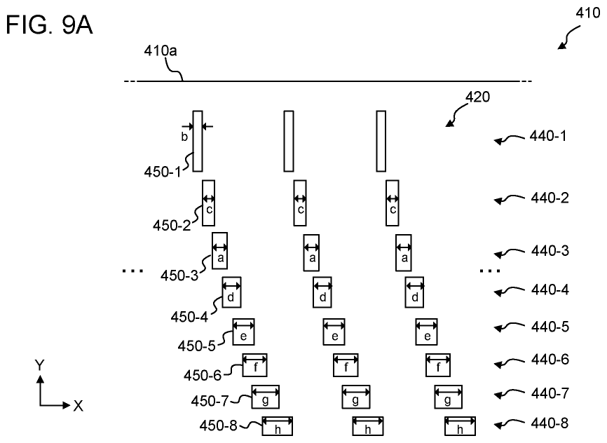

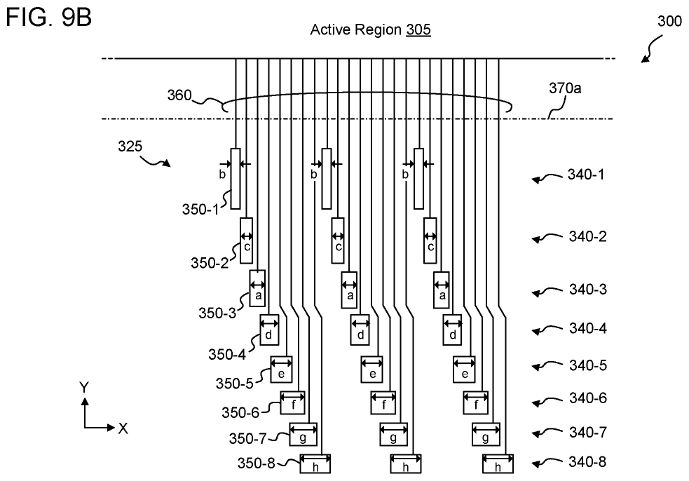

FIG. 9A is a partial enlarged view of the output bump array 420 of FIG. 8, according to one or more embodiments. The output bump array 420 is configured as shown in the right part of FIG. 7. In the shown embodiment, the output bump array 420 has a “staggered” bump arrangement in which bumps are arranged in a plurality of rows with corresponding bumps of adjacent rows offset from each other. The output bump array 420 includes a plurality of bump rows 440 each including a plurality of bumps 450 aligned in the horizontal planar direction (i.e., the X-axis direction), wherein the corresponding bumps 450 in adjacent bump rows 440 are located offset from each other in the horizontal planar direction. In the shown example, the output bump array 420 includes eight bump rows 440-1, 440-2, 440-3, 440-4, 440-5, 440-6, 440-7, and 440-8. The bump row 440-1 is the closest to the long edge 410a, the bump row 440-2 is the second closest to the long edge 410a, the bump row 440-3 is the third closest to the long edge 210a, and so on. The bumps 450-2 of the bump row 440-2 are located offset in the horizontal planar direction from the corresponding bumps 450-1 of the bump row 440-1, the bumps 450-3 of the bump row 440-3 are located offset in the horizontal planar direction from the corresponding bumps 450-2 of the bump row 440-2, and so on. While eight bump rows 440 are shown in FIG. 9A, the output bump array 420 may include fewer or more than eight bump rows. In other embodiments, the output bump array 420 may be arranged in a bump arrangement in which corresponding bumps 450 in the bump rows 440-1 to 440-8 are aligned in the vertical planar direction. In such embodiments, the bumps 450-2 of the bump row 440-2 may be aligned with the corresponding bumps 450-1 of the bump row 440-1 in the vertical planar direction, the bumps 450-3 of the bump row 440-3 may be alighted with the corresponding bumps 450-2 of the bump row 440-2 in the vertical planar direction, and so on.

As discussed above in relation to FIG. 7, the horizontal widths of the bumps 450-1, 450-2, 450-3, 450-4, 450-5, 450-6, 450-7, and 450-8 are narrower as the distance from the long edge 410a of the semiconductor chip 410 decreases. More specifically, the bumps 450-1, 450-2, 450-3, 450-4, 450-5, 450-6, 450-7, and 450-8 have horizontal widths of “b”, “c”, “a”, “d”, “e”, “f”, “g”, and “h”, respectively, where b<c<a<d<e<f<g<h. Further, the vertical heights of the bumps 450-1, 450-2, 450-3, 450-4, 450-5, 450-6, 450-7, and 450-8 decrease as the distance from the long edge 410a of the semiconductor chip 410 increases. More specifically, the bumps 450-1 of the bump row 440-1, which is the closest to the long edge 410a of the semiconductor chip 410, have the largest vertical height, and the bumps 450-2 of the bump row 440-2, which is the second closest to the long edge 410a of the semiconductor chip 410, have the second largest vertical height, the bumps 450-3 of the bump row 440-3, which is the third closest to the long edge 410a of the semiconductor chip 410, have the third largest vertical height, and so on. In one or more embodiments, the horizontal widths and vertical heights of the respective bumps 450-1 to 450-8 may be adjusted such that the areas (or planar areas) of the bumps 450-1 to 450-8 are substantially the same as discussed in relation to FIG. 7.

FIG. 9B is a partial enlarged view showing an example configuration of a display panel 300 driven by the display driver IC 400 of FIG. 8, according to one or more embodiments. Shown in FIG. 9B is the portion of the display panel 300 that is coupled to the portion of the output bump array 420 shown in FIG. 9A. The display panel 300 includes an active region 305 and a bond pad array 325. The active region 305 may include an array of pixels, source lines, gate lines, and other circuit elements arranged according to the type of the display panel 300 (e.g., multiplexers configured to select source lines). The bond pad array 325 includes a plurality of bond pad rows 340-1, 340-2, 340-3, 340-4, 340-5, 340-6, 340-7, and 340-8, each including an array of bond pads 350 aligned in the horizontal planar direction. The bond pads 350 of the bond pad rows 340-1 to 340-8 may be also referred to as the bond pads 350-1 to 350-8, respectively. The bond pad rows 340-1 to 340-8 may be collectively referred to as the bond pad rows 340 when the bond pad rows 340-1 to 340-8 are not distinguished from each other.

The bond pads 350 of each bond pad row 340 are respectively bonded to corresponding bumps 450 of the corresponding bump row 440. The bond pads 350-1 of the bond pad rows 340-1 are bonded to the corresponding bumps 450-1 of the bump row 440-1, and the bond pads 350-2 of the bond pad rows 340-2 are bonded to the corresponding bumps 450-2 of the bump row 440-2, and so on. More specifically, the bond pads 350-j of the bond pad rows 340-j are bonded to the corresponding bumps 450-j of the bump row 440-j, where j is any integer from one to eight.

The planar shapes (e.g., the widths in the horizontal planar (or X-axis) direction and the heights in the vertical planar (or Y-axis) direction) of the bond pads 350 are substantially the same as those of the corresponding bumps 450. Since the horizontal widths of the bumps 450-1, 450-2, 450-3, 450-4, 450-5, 450-6, 450-7, and 450-8 are narrower as the distance from the long edge 410a of the semiconductor chip 410 decreases, the horizontal widths of the bond pads 350-1, 350-2, 350-3, 350-4, 350-5, 350-6, 350-7, and 350-8 are narrower as the distance from the long edge 410a of the semiconductor chip 410 decreases. More specifically, since the bumps 450-1, 450-2, 450-3, 450-4, 450-5, 450-6, 450-7, and 450-8 have horizontal widths of “b”, “c”, “a”, “d”, “e”, “f”, “g”, and “h”, respectively, as described above, the bond pads 350-1, 350-2, 350-3, 350-4, 350-5, 350-6, 350-7, and 350-8 have horizontal widths of “b”, “c”, “a”, “d”, “e”, “f”, “g”, and “h”, respectively, where b<c<a<d<e<f<g<h.

Further, in one or more embodiments, the vertical heights of the bond pads 350-1, 350-2, 350-3, 350-4, 350-5, 350-6, 350-7, and 350-8 are adjusted to decrease as the distance from the long edge 410a of the semiconductor chip 410 increases. More specifically, the bond pads 350-1 of the bond pad row 340-1, which is the closest to the long edge 410a of the semiconductor chip 410, have the largest vertical height, the bond pads 350-2 of the bond pad row 340-2, which is the second closest to the long edge 410a of the semiconductor chip 410, have the second largest vertical height, the bond pads 350-3 of the bond pad row 340-3, which is the third closest to the long edge 410a of the semiconductor chip 410, have the third largest vertical height, and so on. Further, similarly to the bumps 450-1 to 450-8 of the bump array 420, the horizontal widths and vertical heights of the respective bond pads 350-1 to 350-8 may be adjusted such that the areas (or planar areas) of the bond pads 350-1 to 350-8 are the same, according to one or more embodiments.

The bond pads 350-1 to 350-8 are coupled to routing traces 360, respectively. The routing traces 360 provide electrical connections between the bond pads 350 and circuit elements provided in the active region 305 of the display panel 300, such as source lines, pixels, and multiplexers configured to select source lines coupled to the bond pads 350, if such multiplexers are provided in the active region 305. Signals and/or voltages output from the bumps 450 of the display driver IC 400 (e.g., data voltages for driving the pixels of the display panel 300) are provided to the active region 305 via the corresponding bond pads 350 and routing traces 360. As shown in FIG. 9B, where the dashed-dotted line 370a indicates the projection of the long edge 410a of the display driver IC 400 onto the display panel 300, the routing traces 360 pass under the long edge 410a of the display driver IC 400.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Exemplary embodiments are described herein. Variations of those exemplary embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

The invention claimed is:

1. An integrated circuit, comprising:
a semiconductor chip comprising a first edge oriented in a first planar direction;
a first bump row comprising a plurality of first bumps aligned in the first planar direction along the first edge; and
a second bump row comprising a plurality of second bumps aligned in the first planar direction, the second bump row being located farther from the first edge of the semiconductor chip than the first bump row,
wherein a first width of the first bumps in the first planar direction is narrower than a second width of the second bumps in the first planar direction.

2. The integrated circuit of claim 1, wherein a first height of the first bumps in a second planar direction perpendicular to the first planar direction is greater than a second height of the second bumps in the second planar direction.

3. The integrated circuit of claim 2, wherein a first area of one of the plurality of first bumps is substantially equal to a second area of one of the plurality of second bumps.

4. The integrated circuit of claim 1, wherein each of the second bumps is positioned offset from a corresponding one of the first bumps in the first planar direction.

5. The integrated circuit of claim 1, further comprising a third bump row comprising a plurality of third bumps aligned in the first planar direction,
wherein the third bump row is located farther from the first edge of the semiconductor chip than the second bump row, and
wherein the second width of the second bumps in the first planar direction is narrower than a third width of the third bumps in the first planar direction.

6. The integrated circuit of claim 5, wherein a first height of the first bumps in a second planar direction perpendicular to the first planar direction is greater than a second height of the second bumps in the second planar direction,
wherein the second height of the second bumps is greater than a third height of the third bumps in the second planar direction, and
wherein one of the plurality of first bumps, one of the plurality of second bumps and one of the plurality of third bumps, respectively, have a substantially equal area.

7. The integrated circuit of claim 1, wherein the integrated circuit is a display driver integrated circuit (IC) configured to drive a display panel.

8. The integrated circuit of claim 7, wherein the display driver IC is configured to:
generate data voltages with which pixels of the display panel are driven; and
provide the data voltages to the display panel via the first bumps and the second bumps.

9. The integrated circuit of claim 7, wherein the semiconductor chip further comprises a second edge oriented in a second planar direction perpendicular to the first planar direction, and
wherein the second edge is shorter than the first edge.

10. A display device, comprising:
a display panel; and
a display driver integrated circuit (IC) bonded on the display panel, the display driver IC comprising:
a semiconductor chip comprising a first edge oriented in a first planar direction;
a first bump row comprising a plurality of first bumps aligned in the first planar direction along the first edge; and
a second bump row comprising a plurality of second bumps aligned in the first planar direction, the second bump row being located farther from the first edge of the semiconductor chip than the first bump row,
wherein a first width of the first bumps in the first planar direction is narrower than a second width of the second bumps in the first planar direction.

11. The display device of claim 10, wherein a first height of the first bumps in a second planar direction perpendicular to the first planar direction is greater than a second height of the second bumps in the second planar direction.

12. The display device of claim 11, wherein a first area of one of the plurality of first bumps is substantially equal to a second area of one of the plurality of second bumps.

13. The display device of claim 10, wherein each of the second bumps is positioned shifted from a corresponding one of the first bumps in the first planar direction.

14. The display device of claim 10, wherein the display panel comprises:
an active area that comprises pixels;
a plurality of first bond pads bonded to the plurality of first bumps of the first bump row, respectively;
a plurality of second bond pads bonded to the plurality of second bumps of the second bump row, respectively;
a plurality of first routing traces that electrically couple the first bond pads to the active area; and
a plurality of second routing traces that electrically couple the first bond pads to the active area.

15. The display device of claim 14, wherein the plurality of first and second routing traces comprises routing trace portions that extend in a second planar direction perpendicular to the first planar direction to pass under the first edge of the display driver IC.

16. The display device of claim 10, the display driver IC further comprises a third bump row comprising a plurality of third bumps aligned in the first planar direction,
wherein the third bump row is located farther from the first edge of the semiconductor chip than the second bump row,
wherein each of the third bumps is positioned shifted from a corresponding one of the second bumps in the first planar direction, and
wherein the second width of the second bumps in the first planar direction is narrower than a third width of the third bumps in the first planar direction.

17. The display device of claim 16, wherein a first height of the first bumps in a second planar direction perpendicular to the first planar direction is greater than a second height of the second bumps in the second planar direction,
wherein the second height of the second bumps is greater than a third height of the third bumps in the second planar direction, and
wherein one of the plurality of first bumps, one of the plurality of second bumps and one of the plurality of third bumps, respectively, have a substantially equal area.

18. A method, comprising:
generating data voltages by a display driver IC comprising:
a semiconductor chip comprising a first edge oriented in a first planar direction;
a first bump row comprising a plurality of first bumps aligned in the first planar direction along the first edge; and
a second bump row comprising a plurality of second bumps aligned in the first planar direction, the second bump row being located farther from the first edge of the semiconductor chip than the first bump row,
wherein a first width of the first bumps in the first planar direction is narrower than a second width of the second bumps in the first planar direction; and
providing the data voltages to a display panel via the plurality of first bumps and the plurality of second bumps.

19. The method of claim 18, wherein a first height of the first bumps in a second planar direction perpendicular to the first planar direction is greater than a second height of the second bumps in the second planar direction.

20. The method of claim 19, wherein a first area of one of the plurality of first bumps is substantially equal to a second area of one of the plurality of second bumps.
